(19) United States
(12) Patent Application Publication
(10) Pub. No.: US 2013/0234326 A1
(43) Pub. Date: Sep. 12, 2013

(54) SEMICONDUCTOR APPARATUS AND METHOD FOR MANUFACTURING THE SAME

(71) Applicants: Chul KIM, Gyeonggi-do (KR); Jae Jin LEE, Gyeonggi-do (KR); Jong Chern LEE, Gyeonggi-do (KR)

(72) Inventors: Chul KIM, Gyeonggi-do (KR); Jae Jin LEE, Gyeonggi-do (KR); Jong Chern LEE, Gyeonggi-do (KR)

(73) Assignee: SK HYNIX INC., Icheon-si (KR)

(21) Appl. No.: 13/604,481

(22) Filed: Sep. 5, 2012

(30) Foreign Application Priority Data
Dec. 29, 2011 (KR) 10-2011-0146441

(51) Int. Cl. H01L 23/00; H01L 21/82

(52) U.S. Cl. CPC H01L 23/562; H01L 21/82
USPC 257/738; 438/107

(57) ABSTRACT

A semiconductor apparatus comprises of a first semiconductor chip having a through silicon via (TSV) and a second semiconductor chip also having a TSV, wherein the respective semiconductor chips are stacked vertically and are connected through a conductive connection member without the assistance of an additional bump between the conductive connection member and the second semiconductor chip.

### CROSS-REFERENCES TO RELATED APPLICATION

The present application claims priority under 35 U.S.C. §119(a) to Korean application number 10-2011-0146441, filed on Dec. 29, 2011, in the Korean Intellectual Property Office, which is incorporated herein by reference in its entirety.

### BACKGROUND

1. Technical Field

The present invention relates generally to a semiconductor apparatus, and more particularly, to a semiconductor apparatus having a plurality of semiconductor chips stacked therein and a method for manufacturing the same.

2. Related Art

For high integration of semiconductor products, stacking a plurality of semiconductor chips in a three-dimensional manner is considered as an option.

In a semiconductor apparatus having a stack structure, a more simplified process is preferred when stacking the semiconductor chips to reduce the manufacturing cost and improve the performance characteristics, while allowing the mass production of the semiconductor apparatuses. However, with the increase in the number and size of semiconductor chips stacked therein, the available interconnection area for internal electrical connection of the semiconductor apparatus may become insufficient.

Considering this aspect, a semiconductor apparatus using through silicon vias (TSVs) has been proposed as an example of a stack package.

The semiconductor apparatus using TSVs refers to a semiconductor apparatus including a plurality of semiconductor chips, which are physically and electrically connected through the TSVs formed inside the semiconductor chips.

Such a conventional semiconductor apparatus using TSVs may include semiconductor chips connected as illustrated in FIG. 1.

FIG. 1 is a diagram illustrating a part of the conventional semiconductor apparatus using TSVs.

Referring to FIG. 1, the conventional semiconductor apparatus using TSVs includes a first semiconductor chip 110 having a TSV 111 and a first bump 113 formed therein, a semiconductor chip 130 having a TSV 131 and a second bump 133 formed therein, and a connection member 120 formed of a conductive material such as a solder ball 121 for electrically connecting the first and second semiconductor chips 110 and 130.

In the conventional semiconductor apparatus using TSVs, the TSV 111, the first bump 113, the solder ball 121, and a third bump 122 are successively connected. The reference numerals 112, 123, and 132 represent insulation layers.

However, the conventional semiconductor apparatus using TSVs has a problem in that the bonding surface between the third bump 122 of the connection member 120 and the TSV 131 of the semiconductor chip 130 may be deteriorated by various stresses (for example, temperature, pressure and the like) which occur during a semiconductor chip stack process.

### SUMMARY

A semiconductor apparatus capable of reducing a defect by improving a bonding surface between semiconductor chips in a structure having a plurality of semiconductor chips stacked therein, thereby improving the yield, and a method for manufacturing the same are described herein.

In an embodiment of the present invention, there is provided a semiconductor apparatus including a plurality of semiconductor chips stacked in a vertical direction and having a through silicon via (TSV). The respective semiconductor chips are stacked through a conductive connection member without the assistance of an additional bump.

In an embodiment of the present invention, a semiconductor apparatus includes: a first semiconductor chip including a first TSV and a first bump to enable signal exchange with the outside through the first TSV; a second semiconductor chip including a second TSV and a second bump to enable signal exchange with the first semiconductor chip through the second TSV; and a conductive connection member formed between the first bump and the second TSV.

In an embodiment of the present invention, a method for manufacturing a semiconductor apparatus includes the steps of: forming a first semiconductor chip including a first TSV; forming a second semiconductor chip including a second TSV; and forming a conductive connection member between the first and second semiconductor chips such that the first and second semiconductor chips are stacked in a vertical direction.

### BRIEF DESCRIPTION OF THE DRAWINGS

Features, aspects, and embodiments are described in conjunction with the attached drawings, in which:

FIG. 1 is a diagram illustrating a part of the conventional semiconductor apparatus using TSVs;

FIG. 2 is a diagram illustrating a part of a semiconductor apparatus according to one embodiment of the present invention; and

FIGS. 3 to 10 are diagrams illustrating a method for manufacturing a semiconductor apparatus according to an embodiment of the present invention.

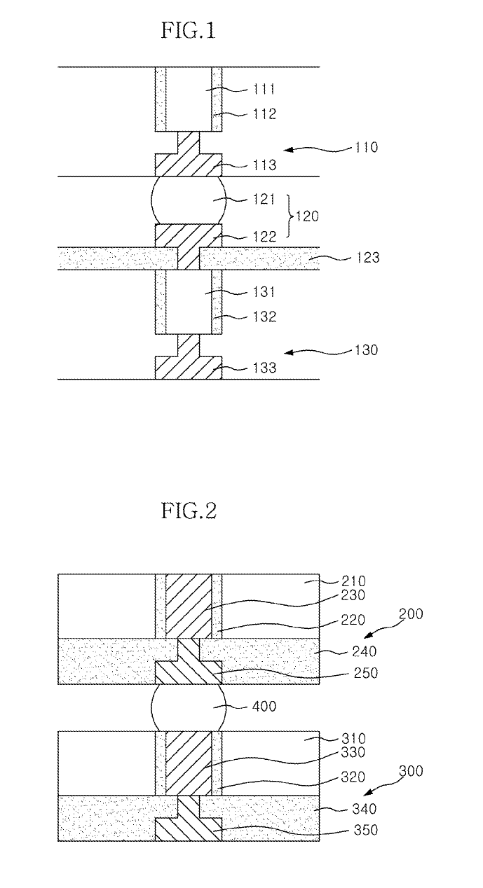

### DETAILED DESCRIPTION

Hereinafter, a semiconductor apparatus and a method for manufacturing the same according to the present invention will be described below with reference to the accompanying drawings through various embodiments.

FIG. 2 is a diagram illustrating a part of a semiconductor apparatus according to an embodiment of the present invention.

Referring to FIG. 2, the semiconductor apparatus according to an embodiment of the present invention includes a first semiconductor chip 200, a semiconductor chip 300, and a conductive connection member 400 for connecting the first and second semiconductor chips 200 and 300.

The first semiconductor chip 200 includes a first TSV 230, an insulation layer 220, and a first bump 250. The first TSV 230 serves to electrically connect another semiconductor chip (not illustrated) to a first semiconductor substrate 210. The insulation layer 220, which may be formed of oxide, is formed at both sides of the first TSV 230 so as to insulate the first TSV 230. The first bump 250 is electrically connected to the first TSV 230. The reference numeral 240 represents an insulation layer.

The semiconductor chip 300 includes a second TSV 330, an insulation layer 320, and a second bump 350. The second TSV 330 is electrically connected to the first semiconductor chip 200. The insulation layer 320, which may be formed of oxide, is formed in both sides of the second TSV 330 so as to insulate the second TSV 330. The second bump 350 serves to electrically connect the second TSV 330 to another semiconductor chip (not illustrated) which is to be stacked. The reference numeral 340 represents an insulation layer.

The conductive connection member 400 connects the first and second semiconductor chips 200 and 300 through a flip-chip method, and may, for example, include a solder ball.

Although FIG. 2 does not illustrate the metal lines, it should be readily understood that a metal line is provided between the TSV and the bump of each semiconductor chip in the respective semiconductor chips of the semiconductor apparatus according to an embodiment of the present invention.

As described above, the semiconductor apparatus according to an embodiment of the present invention is constructed in such a manner that the first and second semiconductor chips 200 and 300 are connected only through the conductive connection member 400. Therefore, this prevents formation of a defect on the bonding surface between the semiconductor chips, for example, a defect which occurs on the bonding surface between the bump and the TSV in the conventional semiconductor apparatus, to thereby increase the yield of the semiconductor apparatus.

A method for manufacturing the semiconductor apparatus according to an embodiment of the present invention will be described.

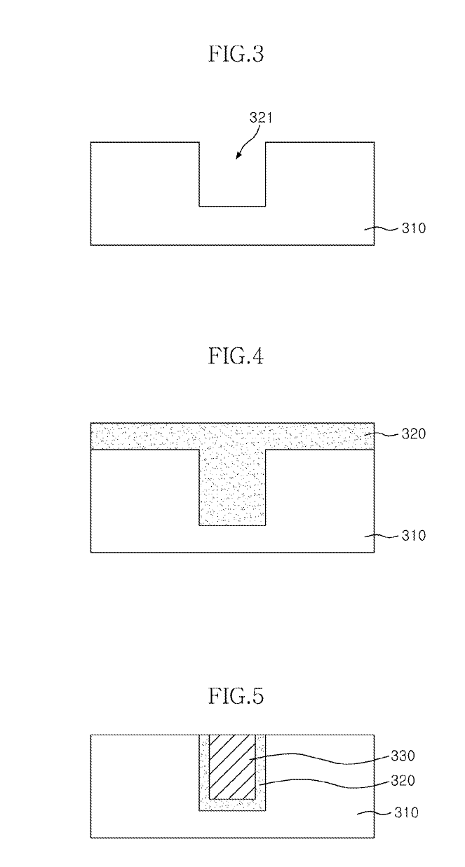

FIGS. 3 to 10 are diagrams illustrating the method for manufacturing the semiconductor apparatus according to an embodiment of the present invention.

Referring to FIG. 3, a hole 321 for forming a TSV is formed in a semiconductor substrate 310, which may be formed of silicon (Si).

Referring to FIG. 4, a first insulation layer 320 is formed on the surfaces of the hole 321 and the silicon substrate 310.

Referring to FIG. 5, the first insulation layer 320 is etched to be left only on both sidewalls and the bottom of the hole 321, and a TSV 330 is formed by burying a conductive metal in the hole 321. Here, the TSV 330 may be formed by depositing Cu, and the deposition of Cu may be performed by an electroplating method.

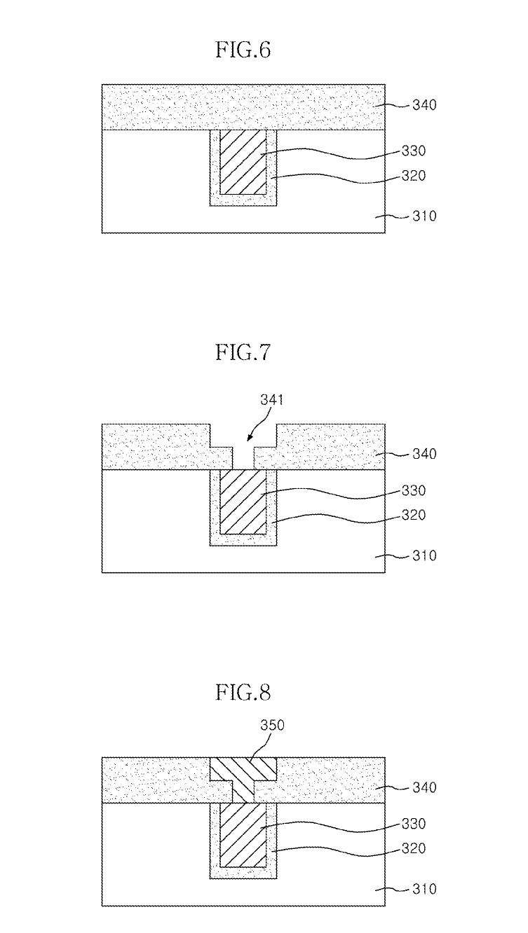

Referring to FIG. 6, a second insulation layer 340 is formed over the silicon substrate 310 including the TSV 330.

Referring to FIG. 7, a bump hole 341 is formed by etching the resultant structure, in order to form a bump which enables signal exchange with another semiconductor chip to be stacked. The etching is performed until the TSV 330 is exposed. The bump hole 341 may be formed in various shapes, but according to an embodiment of the present invention as shown in FIG. 7, the bump hole 341 may be formed in a T shape. Without being limited thereto, the bump hole 341 may be formed with a smaller width than the TSV 330.

Referring to FIG. 8, the bump hole 341 is filled with a conductive metal to form a bump 350, which enables signal transmission.

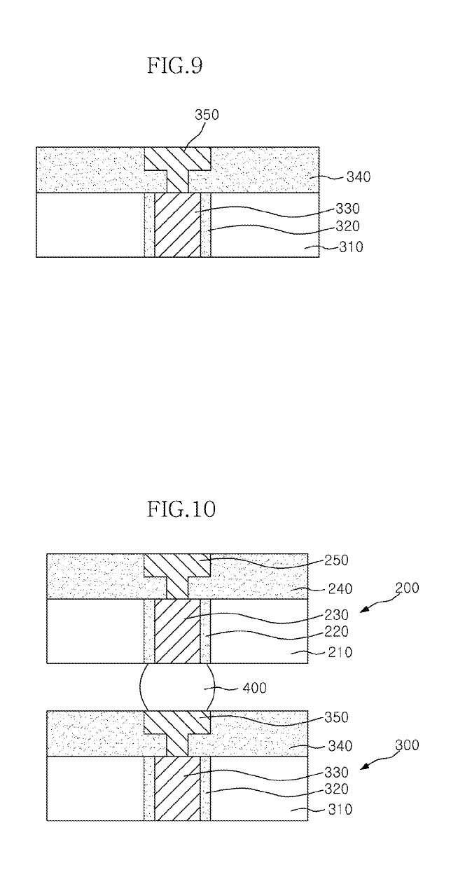

Referring to FIG. 9, the rear surface of the silicon substrate 310 is back-ground to a semiconductor chip thickness. The back-grinding is performed until the TSV 330 is exposed. The TSV 330 is exposed in order to enable a signal connection to the next semiconductor chip.

Referring to FIG. 10, a conductive connection member 400 such as a solder ball is formed in such a way to make a contact with the TSV 330, in order to stack the first and second semiconductor chips 200 and 300. Then, the semiconductor apparatus according to the embodiment of the present invention is completed.

In the semiconductor apparatus and the method for manufacturing the same according to an embodiment of the present invention, the first bump 113 is removed from the conventional structure as described in FIG. 10, allowing for the conductive connection member 400 and both the TSV 230 and the second bump 350 to be directly connected, thereby suppressing a connection defect between the bump 350 and the TSV 230. Therefore, it is possible to increase the yield of the semiconductor apparatus.

Furthermore, removing the first bump 113 from the conventional structure may simplify the manufacturing process and thereby reduce the manufacturing cost of the semiconductor apparatus.

While certain embodiments have been described above, it will be understood to those skilled in the art that the embodiments described are by way of example only. Accordingly, the apparatus and method described herein should not be limited based on the described embodiments. Rather, the apparatus and method described herein should only be limited in light of the claims that follow when taken in conjunction with the above description and accompanying drawings.

What is claimed is:

1. A semiconductor apparatus comprising:
a first semiconductor chip having a through silicon via (TSV); and
a second semiconductor chip also having a TSV,
wherein the respective semiconductor chips are stacked vertically and are connected through a conductive connection member without the assistance of an additional bump between the conductive connection member and the second semiconductor chip.

2. The semiconductor apparatus according to claim 1, wherein the first semiconductor chip having the TSV comprises:
a first bump to enable signal exchange with the TSV of the second semiconductor chip.

3. The semiconductor apparatus according to claim 2, wherein the conductive connection member is formed between the first bump of the first semiconductor chip and the TSV of the second semiconductor chip.

4. The semiconductor apparatus according to claim 3, wherein the conductive connection member is made as a single unit of one or more conductive materials.

5. The semiconductor apparatus according to claim 3, wherein the conductive connection member is a solder ball.

6. A semiconductor apparatus comprising:
a first semiconductor chip comprising:
a first TSV; and
a first bump to enable the first semiconductor chip to exchange signal with the outside through the first TSV;
a second semiconductor chip comprising:
a second TSV; and
a second bump to enable the second semiconductor chip to exchange signal with the first semiconductor chip through the second TSV; and
a conductive connection member having no bump formed between the first bump and the second TSV.

7. The semiconductor apparatus according to claim 6, wherein the conductive connection member is made as a single unit of one or more conductive materials.

8. The semiconductor apparatus according to claim 6, where in the conductive connection member is a solder ball.

9. A semiconductor apparatus comprising:
a first semiconductor chip comprising a first TSV;
a second semiconductor chip comprising:
a second TSV; and
a first bump to enable the second semiconductor chip to exchange signal with the first semiconductor chip through the second TSV; and
a conductive connection member having no bump formed between the first TSV and the first bump.

10. The semiconductor apparatus according to claim 9, wherein the conductive connection member is made as a single unit of one or more conductive materials.

11. The semiconductor apparatus according to claim 9, where in the conductive connection member is a solder ball.

12. A method of manufacturing a semiconductor apparatus, comprising the steps of:
forming a first semiconductor chip comprising a first TSV;
forming a second semiconductor chip comprising a second TSV; and
forming a conductive connection member having no bump between the first and second semiconductor chips such that the first and second semiconductor chips are stacked.

13. The method according to claim 12, wherein each of the steps of forming the first and second semiconductor chips, comprises the steps of:
forming a substrate having a hole formed therein;
depositing a first insulation layer in the hole and over the substrate;
etching the resultant structure such that the first insulation layer is left only on sidewalls of the hole, and forming a TSV by depositing a conductive metal in the hole;
depositing a second insulation layer over the TSV;
forming a bump hole by etching the second insulation layer to expose the TSV, and forming a bump by depositing a conductive metal in the bump hole; and
back-grinding the rear surface of the semiconductor substrate to expose the TSV.

14. The method according to claim 13, wherein the conductive connection member is interposed between the TSV of the first semiconductor chip and the bump of the second semiconductor chip.

15. The method according to claim 14, wherein the conductive connection member is made as a single unit of one or more conductive materials.

16. The method according to claim 14, wherein the conductive connection member is a solder ball.
